(19) United States
(12) Patent Application Publication
(10) Pub. No.: US 2023/0121639 A1
(43) Pub. Date: Apr. 20, 2023

(54) SELECTIVE WET ETCH COMPOSITION AND METHOD

(71) Applicant: ENTEGRIS, INC., Billerica, MA (US)

(72) Inventors: Hyongpyo Hong, Bundang-gu (KR); Chia-Jung Hsu, Taipei City (TW); Atanu K. Das, Southbury, CT (US)

(21) Appl. No.: 17/968,286

(22) Filed: Oct. 18, 2022

Related U.S. Application Data
(60) Provisional application No. 63/257,760, filed on Oct. 20, 2021.
(60) Provisional application No. 63/344,436, filed on May 20, 2022.

(51) Int. Cl. C09K 13/06; H05K 3/06

(52) U.S. Cl. CPC C09K 13/06; H05K 3/06

(57) ABSTRACT

A composition and method for etching molybdenum-containing film on a microelectronic device substrate is provided. A microelectronic device substrate is contacted with the composition of the invention for a time sufficient to at least partially remove the molybdenum-containing film. The composition comprises at least one oxidizing agent, at least one complexing agent, at least one cationic surfactant, and has a pH of from about 7.5 to about 13. The etchant composition selectively removes molybdenum at an etch rate of about 20 to 50 Å/minute at room temperature, with improved uniformity of removal.

### CROSS-REFERENCE TO RELATED APPLICATIONS

This application claims the benefit under 35 USC 119 of U.S. Provisional Patent Application Nos. 63/257,760, filed Oct. 20, 2021, and 63/344,436 filed on May 20, 2022, the disclosure of each is hereby incorporated herein by reference in its entirety.

### TECHNICAL FIELD

The invention belongs generally to the etching or removal of molybdenum-containing materials from microelectronic device substrates.

### BACKGROUND

Typically, tungsten and tungsten-based materials are used as the electrodes in 3D-NAND fabrication. However, tungsten materials have been found to be sensitive to various etchant compositions. For example, in a process using an W electrode, acidic compositions including phosphoric acid and nitric acid used for electrode isolation (the so-called “W recess”) were found to cause partial etching of the tungsten layer.

Currently, 3D-NAND structures are finding utility in memory devices. In order to achieve better efficiency in memory performance, 3D-NAND manufacturers have investigated other materials that can lead to superior performance in memory devices. In particular, many 3D-NAND manufacturers have replaced the W layers with molybdenum. As a result, manufacturers require etchant compositions that can selectively remove the Mo in the recesses without removing materials such as TEOS and aluminum oxide. Of particular interest is an etchant composition that can selectively remove molybdenum at an etch rate such that each recess achieves a substantially the same targeted etch depth under the controlled etching conditions.

### SUMMARY

A composition and method for selectively etching a molybdenum-containing film on a microelectronic device substrate is provided. A microelectronic device substrate is contacted with the composition of the invention for a time sufficient to at least partially remove the molybdenum-containing film. The composition comprises, consists, or consists essentially of at least one oxidizing agent, at least one cationic surfactant, water, and an amount of a pH adjustor necessary to achieve a pH of from about 7 to about 13. The etchant composition selectively removes molybdenum at an etch rate of about 20 to 50 Å/minute at room temperature, with improved uniformity of removal.

### BRIEF DESCRIPTION OF THE DRAWINGS

FIG. 1 is a simplified depiction of a microelectronic device substrate having molybdenum, TEOS, and Aluminum oxide surfaces. The data set forth in the Examples characterizes the quantity and uniformity of etching relative to the depth of the device, from the top, to the middle, and to the bottom.

FIG. 2 is a bar graph showing the Z range for various experiments reflected in the Examples, illustrating the improved roughness parameters for molybdenum-containing films subjected to etching using the compositions of the invention. (Rz is the mean value of a of roughness depths of consecutive sampling lengths. Z is the sum of the height of the highest peaks and the lowest valley depth within a sampling length.)

FIG. 3 is a scanning electron micrograph (SEM) of various sample surfaces as illustrated in the Examples, showing the roughness (Rz) is much higher in samples which were etched with compositions not containing a cationic surfactant.

### DETAILED DESCRIPTION

As used in this specification and the appended claims, the singular forms “a”, “an”, and “the” include plural referents unless the content clearly dictates otherwise. As used in this specification and the appended claims, the term “or” is generally employed in its sense including “and/or” unless the content clearly dictates otherwise.

The term “about” generally refers to a range of numbers that is considered equivalent to the recited value (e.g., having the same function or result). In many instances, the term “about” may include numbers that are rounded to the nearest significant figure.

Numerical ranges expressed using endpoints include all numbers subsumed within that range (e.g., 1 to 5 includes 1, 1.5, 2, 2.75, 3, 3.80, 4 and 5).

The present invention provides a selective etching composition comprising:

at least one oxidizing agent;

at least one cationic surfactant;

water; and

an amount of a pH adjustor necessary to achieve a pH of about 7 to about 13, and optionally comprising one or more of:

at least one complexing agent, at least one pH buffering agent, or at least one oxidizing agent stabilizer.

The compositions of the invention are useful for etching, i.e., removing, molybdenum-containing films from the surface of microelectronic device substrates. In particular, the compositions show excellent selectivity for molybdenum-containing materials while limiting damage to surfaces comprising TEOS and aluminum oxide.

As used herein, the term “microelectronic device” corresponds to semiconductor substrates, including 3D NAND structures, flat panel displays, and microelectromechanical systems (MEMS), manufactured for use in microelectronic, integrated circuit, or computer chip applications. It is to be understood that the term “microelectronic device” is not meant to be limiting in any way and includes any substrate that includes, for example, a negative channel metal oxide semiconductor (nMOS) and/or a positive channel metal oxide semiconductor (pMOS) transistor and will eventually become a microelectronic device or microelectronic assembly. Such microelectronic devices generally contain at least one substrate, which can be chosen from, for example, silicon, SiO₂, Si₃N₄, OSG, FSG, silicon carbide, hydrogenated silicon carbide, silicon nitride, hydrogenated silicon nitride, silicon carbonitride, hydrogenated silicon carbonitride, boronitride, antireflective coatings, photoresists, germanium, germanium-containing, boron-containing, Ga/As, a flexible substrate, porous inorganic materials, metals such as copper and aluminum, and diffusion barrier layers such as but not limited to TiN, Ti(C)N, TaN, Ta(C)N, Ta, W, or WN. The films are compatible with a variety of subsequent processing steps such as, for example, chemical mechanical planarization (CMP) and anisotropic etching processes.

The microelectronic device comprises a molybdenum-containing material. As used herein, “molybdenum-containing material” and “molybdenum” include any material comprising greater than 50 weight % elemental molybdenum, based on the total weight of the material. Examples of molybdenum-containing materials include, but are not limited to, pure molybdenum (Mo) and alloys or mixtures containing molybdenum, as well as molybdenum oxides and carbides. For example, it is known that molybdenum deposited during the manufacture of microelectronic devices may also contain aluminum (Mo—Al) or titanium (Mo—Ti), generally at less than 5 wt %, and “molybdenum” would include these materials. It should be understood by the person skilled in the art that the chemical formula for the various molybdenum species can vary based on the oxidation state of the molybdenum ion, wherein the common oxidation states of molybdenum are −3, −1, +1, +2, +3, +4, +5 or +6.

The oxidizing agents of the composition are those species which are capable of oxidizing molybdenum to produce a soluble molybdenum species, for example, under alkaline pH conditions. Examples include hydrogen peroxide (H₂O₂), FeCl₃, FeF₃, Fe(NO₃)₃, Sr(NO₃)₂, CoF₃, MnF₃, oxone, (2KHSO₅·KHSO₄·K₂SO₄), nitric acid (HNO₃), ammonium peroxomonosulfate, ammonium chlorite (NH₄ClO₂), ammonium chlorate (NH₄ClO₃), ammonium iodate (NH₄IO₃), ammonium nitrate (NH₄NO₃), ammonium perborate (NH₄BO₃), ammonium perchlorate (NH₄ClO₄), ammonium periodate (NH₄IO₄), ammonium persulfate ((NH₄)₂S₂O₈), ammonium hypochlorite (NH₄ClO), ammonium tungstate ((NH₄)₁₀H₂(W₂O₇)), sodium persulfate (Na₂S₂O₈), sodium hypochlorite (NaClO), sodium perborate, potassium iodate (KIO₃), potassium permanganate (KMnO₄), potassium persulfate (K₂S₂O₈), potassium hypochlorite (KClO), tetramethylammonium chlorite ((N(CH₃)₄)ClO₂), tetramethylammonium chlorate ((N(CH₃)₄)ClO₃), tetramethylammonium iodate ((N(CH₃)₄)IO₃), tetramethylammonium perborate ((N(CH₃)₄)BO₃), tetramethylammonium perchlorate ((N(CH₃)₄)ClO₄), tetramethylammonium periodate ((N(CH₃)₄)IO₄), tetramethylammonium persulfate ((N(CH₃)₄)S₂O₈), tetrabutylammonium peroxomonosulfate, peroxomonosulfuric acid, urea hydrogen peroxide ((CO(NH₂)₂)H₂O₂), peracetic acid (CH₃(CO)OOH), t-butyl hydroperoxide, nitrobenzenesulfonate, 1,4-benzoquinone, toluquinone, dimethyl-1,4-benzoquinone, chloranil, alloxan, periodic acid, and combinations thereof. In one embodiment, the oxidizing agent is chosen from hydrogen peroxide, urea-hydrogen peroxide, ammonium persulfate, periodic acid, peracetic acid, or t-butyl hydroperoxide.

The oxidizing agent may be present in any amount effective to remove molybdenum from the microelectronic device, particularly in the presence of other metal layers. In one embodiment, the etchant composition may comprise from about 0.1 weight percent to about 5 weight percent of the oxidizing agent. In other embodiments, the amount of oxidizing agent is from about 0.1 weight percent to about 2 weight percent, or from about 0.1 weight percent to about 1 weight percent. The oxidizing agent may be introduced directly into the composition or may be prepared as part of an oxidizing agent solution and subsequently combined with the remaining components prior to contacting with the microelectronic device. The latter would further prevent decomposition of the oxidizing agent by minimizing the amount of time it is exposed to alkaline conditions.

The composition comprises at least one pH adjustor in an amount necessary to achieve a pH of the composition to be at least about 7. In one embodiment, the pH of the composition is from about 7.5 to about 13 and in another embodiment from about 8 to about 11. Examples of suitable pH adjustors, include but are not limited to, alkali metal hydroxides, alkaline earth metal hydroxides, tetraalkyl ammonium hydroxides (such as tetramethylammonium hydroxide (TMAH), tetraethylammonium hydroxide (TEAH), tetrapropylammonium hydroxide (TPAH), and tetrabutylammonium hydroxide (TB AH)), tributylmethylammonium hydroxide (TB MAH) benzyltrimethylammonium hydroxide (BTMAH), choline hydroxide, ethyltrimethylammonium hydroxide, tris(2-hydroxyethyl)methyl ammonium hydroxide, diethyldimethylammonium hydroxide, tetraalkyl phosphonium hydroxides (such as tetrabutylphosphonium hydroxide (TBPH), tetramethylphosphonium hydroxide, tetraethylphosphonium hydroxide, and tetrapropylphosphonium hydroxide), benzyltriphenylphosphonium hydroxide, methyl triphenylphosphonium hydroxide, ethyl triphenylphosphonium hydroxide, N-propyl triphenylphosphonium hydroxide, and combinations thereof. In one embodiment, the pH adjustor is chosen from tetramethylammonium hydroxide or choline hydroxide.

In certain embodiments, the pH adjustor utilized herein is present in an amount of about 0.1 weight percent to about 10 weight percent, or about 0.1 weight percent to about 8 weight percent, or about 0.1 weight percent to about 5 weight percent.

The composition described herein can be and in one embodiment is substantially devoid of ammonia or ammonium hydroxide. In another embodiment, the etchant composition is ammonia and ammonium hydroxide free. These bases, while effective at raising the pH to the desired level, present substantial health and environmental concerns and would significantly increase costs for handling and mitigation of these issues.

Cationic surfactants are in general salts of quaternary ammonium salts and may be useful for passivating surfaces to enable both selective and uniform removal of molybdenum-containing material. Exemplary cationic surfactants include, but are not limited to, cetyl trimethylammonium bromide (CTAB) (also known as hexadecyltrimethyl ammonium bromide), hexadecyltrimethyl ammonium chloride (CTAC), heptadecanefluorooctane sulfonic acid, tetraethylammonium halides, stearyl trimethylammonium chloride, 4-(4-diethylaminophenylazo)-1-(4-nitrobenzyl)pyridium bromide, cetylpyridinium chloride monohydrate, benzalkonium chloride, benzethonium chloride benzyldimethyldodecylammonium chloride, benzyldimethylhexadecylammonium chloride, hexadecyltrimethylammonium bromide, dimethyldioctadecylammonium chloride, dodecyltrimethylammonium chloride, didodecyldimethylammonium bromide, di(hydrogenated tallow)dimethylammonium chloride, tetraheptylammonium bromide, tetrakis(decyl)ammonium bromide, and oxyphenonium bromide, dimethyldioctadecylammonium chloride, dimethyldihexadecylammonium bromide, di(hydrogenated tallow)dimethylammonium chloride, hexamethonium chloride, trimethyltetradecylammonium chloride, decyltrimethylammonium chloride, and benzyldimethylammonium chloride (BDAC).

In addition to the components discussed above, the composition of the present disclosure may further comprise, consist of, or consist essentially of optional additional components present to further improve and/or enhance the performance of composition for selective removal of molybdenum from a microelectronic device. For example, the etchant composition may optionally further comprise one or more of at least one complexing agent, at least one pH buffering agent, or at least one oxidizing agent stabilizer. The composition may comprise one or more of these components, alone or in any combination. For example, the composition may comprise both a complexing agent and a pH buffering agent. Furthermore, or in addition, the composition may further comprise an oxidizing agent stabilizer added to the composition prior to or in combination with the oxidizing agent.

As used herein, “complexing agent” includes those compounds that are understood by one skilled in the art to be complexing agents, chelating agents and/or sequestering agents. When present, complexing agents will chemically combine with or physically hold the molybdenmun atoms and/or ions to be removed from the microelectronic device using the compositions described herein, improving the etch rate of this material. Suitable complexing agents include, but are not limited to, aminoethylethanolamine, N-methylaminoethanol, aminoethoxyethanol, dimethylaminoethoxyethanol, diethanolamine, N-methyldiethanolamine, monoethanolamine (MEA), triethanolamine (TEA), 1-amino-2-propanol, 2-amino-1-butanol, isobutanolamine, triethylenediamine, 4-(2-hydroxyethyl)morpholine (HEM), ethylenediamine tetraacetic acid (EDTA), m-xylenediamine (MXDA), iminodiacetic acid (IDA), 2-(hydroxyethyl)iminodiacetic acid (HIDA), nitrilotriacetic acid, thiourea, 1,1,3,3-tetramethylurea, urea, urea derivatives, uric acid, alanine, arginine, asparagine, aspartic acid, cysteine, glutamic acid, glutamine, histidine, isoleucine, leucine, lysine, methionine, phenylalanine, proline, serine, threonine, tryptophan, tyrosine, valine, 1-hydroxyethylidene-1,1-diphosphonic acid (HEDP), 1,5,9-triazacyclododecane-N,N′,N″-tris(methylenephosphonic acid) (DOTRP), 1,4,7,10-tetraazacyclododecane-N,N′,N″,N′″-tetrakis(methylenephosphonic acid) (DOTP), nitrilotris(methylene)triphosphonic acid, diethylenetriaminepentakis(methylene phosphonic acid) (DETAP), aminotri(methylene phosphonic acid), bis(hexamethylene)triamine pentamethylene phosphonic acid, 1,4,7-triazacyclononane-N,N′,N″-tris(methylenephosphonic acid (NOTP), hydroxyethyldiphosphonate, nitrilotris(methylene)phosphonic acid, 2-phosphono-butane-1,2,3,4-tetracarboxylic, carboxyethyl phosphonic acid, aminoethyl phosphonic acid, glyphosate, ethylene diamine tetra(methylenephosphonic acid) phenylphosphonic acid, oxalic acid, succinnic acid, maleic acid, malic acid, malonic acid, adipic acid, phthalic acid, lactic acid, citric acid, sodium citrate, potassium citrate, ammonium citrate, tricarballylic acid, trimethylolpropionic acid, tartaric acid, glucuronic acid, 2-carboxypyridine, 4,5-dihydroxy-1,3-benzenedisulfonic acid disodium salt, and combinations thereof. In one embodiment, the complexing agent is chosen from 1-hydroxyethylidene-1,1-diphosphonic acid (HEDP), lactic acid or citric acid.

The complexing agent may be present in any amount effective to improve the etch rate of the molybdenum. For example, when used, the composition may comprise from about 0.1 weight percent to about 20 weight percent of the complexing agent. In another embodiment, the amount of complexing agent is from about 0.5 weight percent to about 15 weight percent, and in another embodiment, from about 1.0 weight percent to about 10 weight percent.

When present, the pH buffering agent can be used to maintain and stabilize the pH of the composition, particularly when used to selectively remove a molybdenum-containing material. The pH buffering agent can be a metal corrosion inhibitor, which protects metal layers against oxidation, thereby stabilizing the pH during the removal of the molybdenum layer, or it may be an ammonium salt, which can buffer the composition against pH changes, extending the shelf life of the composition. Combinations of these may also be used.

For example, in one optional embodiment, the composition comprises at least one metal corrosion inhibitor as a pH buffering agent. The metal corrosion inhibitor can comprise, consist, or consist essentially of one or more corrosion inhibitors including, but not limited to, 5-aminotetrazole, 5-phenyl-benzotriazole, 1H-tetrazole-5-acetic acid, 1-phenyl-2-tetrazoline-5-thione, benzimidazole, methyltetrazole, pyrazoles, 5-amino-1,3,4-thiadiazole-2-thiol (ATDT), benzotriazole (BTA), 1,2,4-triazole (TAZ), 1,2,3-triazole, tolyltriazole, 5-methyl-benzotriazole (mBTA), 5-phenyl-benzotriazole, 5-nitro-benzotriazole, benzotriazole carboxylic acid, 3-amino-5-mercapto-1,2,4-triazole, 1-amino-1,2,4-triazole, hydroxybenzotriazole, 2-(5-amino-pentyl)-benzotriazole, 1-amino-1,2,3-triazole, 1-amino-5-methyl-1,2,3-triazole, 3-amino-1,2,4-triazole (3-ATA), 3-mercapto-1,2,4-triazole, 3-isopropyl-1,2,4-triazole, 5-phenylthiol-benzotriazole, halo-benzotriazoles (halo=F, Cl, Br or I), naphthotriazole, 2-mercaptobenzimidazole (MBI), 2-mercaptobenzothiazole, 4-methyl-2-phenylimidazole, 2-mercaptothiazoline, 5-amino-1,2,4-triazole (5-ATA), 3-amino-5-mercapto-1,2,4-triazole, pentylenetetrazole, 5-phenyl-1H-tetrazole, 5-benzyl-1H-tetrazole, 2,4-diamino-6-methyl-1,3,5-triazine, thiazole, triazine, methyltetrazole, 1,3-dimethyl-2-imidazolidinone, 1,5-pentamethylenetetrazole, 1-phenyl-5-mercaptotetrazole, diaminomethyltriazine, imidazoline thione, 4-methyl-4H-1,2,4-triazole-3-thiol, 4-amino-4H-1,2,4-triazole, 3-amino-5-methylthio-1H-1,2,4-triazole, benzothiazole, imidazole, indiazole, adenine, adenosine, carbazole, N-cyclohexyl-3-aminopropanesulfonic acid, and combinations thereof. Preferably, the metal corrosion inhibitor comprises an azole compound having a pKa of about 9. For example, the metal corrosion inhibitor may be tolyltriazole.

The optional metal corrosion inhibitor may be present in any amount effective to protect metal layers from corrosion and without significantly effecting the etch rate of the molybdenum. Thus, the amount of corrosion inhibitor in the etchant composition is an amount that provides an essentially inhibitor independent Mo etch rate. In particular, when used, the etchant composition may comprise from about 0.001 weight to about 1.0 weight of the corrosion inhibitor. In one embodiment, the amount of corrosion inhibitor is from about 0.05 weight percent to about 0.5 weight percent, and, in another embodiment, from about 0.01 weight percent to about 0.10 weight percent.

In another optional embodiment, the selective etching composition comprises an ammonium salt as a pH buffering agent. Examples of suitable ammonium salts include, for example, salts of ammonium acetate, ammonium bicarbonate, ammonium butyrate, ammonium trifluoroacetate, diammonium monohydrogen phosphate, ammonium dihydrogen phosphate, ammonium phosphonate, and combinations thereof.

In another optional embodiment, the composition further comprises an oxidizing agent stabilizer added to the composition prior to or in combination with the oxidizing agent. Exemplary stabilizers include glycine, serine, proline, leucine, alanine, asparagine, aspartic acid, glutamine, valine, and lysine, nitrilotriacetic acid, iminodiacetic acid, ethylenediaminetetraacetic acid (EDTA), (1,2-cyclohexylenedinitrilo)tetraacetic acid (CDTA), uric acid, tetraglyme, diethylenetriamine pentaacetic acid, propylenedimine tetraacetic acid, ethylenediamine disuccinic acid, sulfanilamide, and combinations thereof. In one embodiment, the oxidizing agent stabilizer is chosen from CDTA and EDTA. In one embodiment, the composition may comprise from about 0.0001 weight percent to about 1.0 weight percent of the oxidizing agent stabilizer. In other embodiments, the amount of oxidizing agent stabilizer present in the composition is about 0.0005 weight percent to about 0.5 weight percent, or about 0.001 weight percent to about 0.1 weight percent.

As discussed above, the composition can be an aqueous composition or can be a semi-aqueous composition. Thus, in some embodiments, the composition comprises water with no additional solvents while, in other embodiments, the composition further comprises water with at least one water-soluble or water-miscible organic solvent. The inclusion of at least one solvent in combination with water may provide additional improvements to the performance of the composition, such as improved planarity of the resulting etched molybdenum surface. Suitable solvents include, for example, methanol, ethanol, isopropanol, butanol, pentanol, hexanol, 2-ethyl-1-hexanol, heptanol, octanol, ethylene glycol, propylene glycol, butylene glycol, butylene carbonate, ethylene carbonate, propylene carbonate, dipropylene glycol, diethylene glycol monomethyl ether, triethylene glycol monomethyl ether, diethylene glycol monoethyl ether, triethylene glycol monoethyl ether, ethylene glycol monopropyl ether, ethylene glycol monobutyl ether, diethylene glycol monobutyl ether, triethylene glycol monobutyl ether, ethylene glycol monohexyl ether, diethylene glycol monohexyl ether, ethylene glycol phenyl ether, propylene glycol methyl ether, dipropylene glycol methyl ether (DPGME), tripropylene glycol methyl ether (TPGME),dipropylene glycol dimethyl ether, dipropylene glycol ethyl ether, propylene glycol n-propyl ether, dipropylene glycol n-propyl ether (DPGPE), tripropylene glycol n-propyl ether, propylene glycol n-butyl ether, dipropylene glycol n-butyl ether, tripropylene glycol n-butyl ether, propylene glycol phenyl ether, 2,3-dihydrodecafluoropentane, ethyl perfluorobutylether, methyl perfluorobutylether, alkyl carbonates, alkylene carbonates, 4-methyl-2-pentanol, diethylene glycol isopropyl methyl ether, and combinations thereof. In one embodiment, the at least one solvent comprises propylene glycol. When used, the solvent may be present in amounts from about 10 weight percent to about 90 weight percent of the total solvent (water plus solvent) used, or about 30 weight percent to about 85 weight percent of the total solvent, or from about 50 weight percent to about 85 weight percent of the total solvent, with the balance being water.

It will be appreciated that it is common practice to make concentrated forms of the compositions to be diluted prior to use. For example, the composition may be manufactured in a more concentrated form and thereafter diluted with at least one solvent at the manufacturer, before use, and/or during use at the fab. Dilution ratios may be in a range from about 0.1 part diluent: 1 part composition concentrate to about 100 parts diluent: 1 part composition concentrate. It should further be appreciated that the compositions described herein include oxidizing agents, which can be unstable over time. Accordingly, the concentrated form can be substantially devoid of oxidizing agent(s) and the oxidizing agent can be introduced to the concentrate or the diluted composition by the manufacturer before use and/or during use at the fab.

The compositions described herein are easily formulated by simple addition of the respective ingredients and mixing to homogeneous condition. Furthermore, the compositions may be readily formulated as single-package formulations or multi-part formulations that are mixed at or before the point of use, preferably multi-part formulations. The individual parts of the multi-part formulation may be mixed at the tool or in a mixing region/area such as an inline mixer or in a storage tank upstream of the tool. It is contemplated that the various parts of the multi-part formulation may contain any combination of ingredients/constituents that when mixed together form the desired composition. The concentrations of the respective ingredients may be widely varied in specific multiples of the composition, i.e., more dilute or more concentrated, and it will be appreciated that the compositions can variously and alternatively comprise, consist or consist essentially of any combination of ingredients consistent with the disclosure herein.

Accordingly, in a further aspect, the invention provides a kit comprising, in one or more containers, one or more components adapted to form the compositions described herein. The containers of the kit must be suitable for storing and shipping said removal composition components, for example, NOWPak® containers (Advanced Technology Materials, Inc., Danbury, Conn., USA). The one or more containers which contain the components of the composition preferably include means for bringing the components in said one or more containers in fluid communication for blending and dispense. For example, referring to the NOWPak® containers, gas pressure may be applied to the outside of a liner in said one or more containers to cause at least a portion of the contents of the liner to be discharged and hence enable fluid communication for blending and dispense. Alternatively, gas pressure may be applied to the head space of a conventional pressurizable container or a pump may be used to enable fluid communication. In addition, the system preferably includes a dispensing port for dispensing the blended composition to a process tool.

Substantially chemically inert, impurity-free, flexible and resilient polymeric film materials, such as high-density polyethylene, can be used to fabricate the liners for said one or more containers. Desirable liner materials are processed without requiring co-extrusion or barrier layers, and without any pigments, UV inhibitors, or processing agents that may adversely affect the purity requirements for components to be disposed in the liner. A listing of desirable liner materials include films comprising virgin (i.e., additive-free) polyethylene, virgin polytetrafluoroethylene (PTFE), polypropylene, polyurethane, polyvinylidene chloride, polyvinylchloride, polyacetal, polystyrene, polyacrylonitrile, polybutylene, and so on. Preferred thicknesses of such liner materials are in a range from about 5 mils (0.005 inch) to about 30 mils (0.030 inch), as for example a thickness of 20 mils (0.020 inch).

Regarding the containers for the kits, the disclosures of the following patents and patent applications are hereby incorporated herein by reference in their respective entireties: U.S. Pat. No. 7,188,644 entitled “APPARATUS AND METHOD FOR MINIMIZING THE GENERATION OF PARTICLES IN ULTRAPURE LIQUIDS;” and U.S. Pat. No. 6,698,619 entitled “RETURNABLE AND REUSABLE, BAG-IN-DRUM FLUID STORAGE AND DISPENSING CONTAINER SYSTEM”, each of which is incorporated herein by reference.

In a further aspect, the invention provides a method of etching molybdenum from a microelectronic device substrate having a molybdenum-containing film thereon, the method comprising contacting the microelectronic device substrate with a composition comprising:
at least one oxidizing agent;
at least one cationic surfactant;
water; and
an amount of a pH adjustor necessary to achieve a pH of about 7 to about 13, and optionally comprising one or more of:
at least one complexing agent,
at least one pH buffering agent, or
at least one oxidizing agent stabilizer.
   for a period of time sufficient to at least partially remove the molybdenum-containing film.

In the method of the invention, the compositions are as set forth herein.

### EXAMPLES

### Example 1

Compositions shown in Table 1 were prepared by combining the various components and adjusting to a pH of 9.5 to 11.5 using (TEAH) as the pH adjustor. The mixture was stirred for 15 min at room temperature to afford a clear solution.

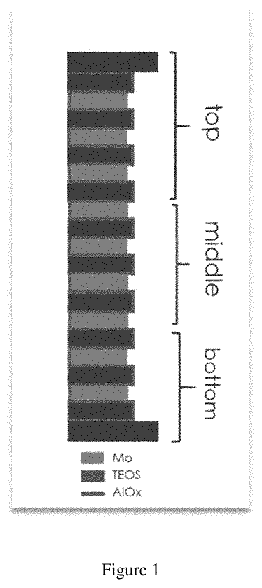

Molybdenum layered pattern coupon, similar to that shown in the simplified depiction of FIG. 1, was placed in 200 gm of the specified composition in a 500 mL Teflon beaker equipped with a stir bar and thermocouple. For this set of experiments, the temperature was set at 50° C. with stirring at 600 rpm. When the temperature was stable, the coupon was placed in the solution for a specified time and subsequently removed to a static DIW rinse for 30 sec followed by flow of DIW for 1 min. The rinsed coupon was dried with in-house nitrogen and analyzed by SEM. Results taken at the top, middle, and bottom of the layered pattern are shown in Table 1.

TABLE 1

| | | | | | Difference |
|---|---|---|---|---|---|
| | | | | Process | (top minus |
| Formulation | Top | Middle | Bottom | temperature/time | bottom) |
| PAN | 565 | 128 | −9 | 35° C./1 minute | 574 |
| SC-1 | 12 | 9.7 | 3.2 | 30° C./5 minutes | 8.8 |
| SPM | 11 | 8 | 7 | 30° C./8 minutes | 4 |
| Control | 55 | 48 | 41 | 50° C./15 minutes | 14 |
| Control + | 32 | 32 | 31 | 50° C./15 minutes | 1 |
| BDAC | | | | | |
| Control | 32 | 24 | 21 | 40° C./25 minutes | 11 |
| Control + | 22 | 21 | 21 | 40° C./25 minutes | 1 |
| BDAC | | | | | |

PAN = H₃PO₄/CH₃COOH/HNO₃
SC-1 = H₂O₂; NH₄OH; H₂O
SPM = H₂O₂; H₂SO₄; H₂O
Control composition = H₂0, periodic acid, lactic acid, TEAH
BDAC = benzyldimethylammonium chloride

As can be seen from this data, the known etching compositions PAN, SC-1, and SPM (comparative examples) showed higher etch rates but undesirable uniformity. Samples including BDAC, a cationic surfactant, showed a major impact on micro and macro uniformity. Additionally, it would be expected that target recess values and process time can be achieved by adjusting the concentration of cationic surfactant.

### Example 2

Compositions of the present disclosure were prepared similarly to those described in Example 1 and are shown in Table 2.

TABLE 2

| Formulation | | | | | | | | | | | | | | |
|---|---|---|---|---|---|---|---|---|---|---|---|---|---|---|
| No. ↓ | A | B | C | D | E | F | G | H | I | J | K | L | pH | Rz |
| Control | 91.9 | 6.0 | 1.2 | 1.0 | — | — | — | — | — | — | — | — | 9.3 | 5.9 |
| 1 | 86.9 | 6.0 | 1.2 | 1.0 | 5.0 | — | — | — | — | — | — | — | 9.4 | 3.5 |
| 2 | 41.6 | 6.2 | 1.2 | 1.0 | 50.0 | — | — | — | — | — | — | — | 10.6 | 3.7 |
| 3 | 91.6 | 2.2 | 1.2 | — | 5.0 | — | — | — | — | — | — | — | 9.4 | 3.4 |
| 4 | 93.6 | 4.8 | 0.6 | 1.0 | — | — | — | — | — | — | — | — | 9.4 | 4.9 |
| 5 | 91.9 | 6.0 | 1.2 | 1.0 | — | 5.0 | — | — | — | — | — | — | 9.1 | 5.4 |
| 6 | 91.9 | 6.0 | 1.2 | 1.0 | — | — | 5.0 | — | — | — | — | — | 9.0 | 5.4 |
| 7 | 91.9 | 6.0 | 1.2 | 1.0 | — | — | — | 5.0 | — | — | — | — | 8.8 | 5.4 |
| 8 | 91.9 | 6.0 | 1.2 | 1.0 | — | — | — | — | — | — | — | — | 11.5 | 2.9 |
| 9 | 91.9 | 6.0 | 1.2 | 1.0 | — | — | — | — | 5.0 | — | — | — | 11.4 | 3.0 |
| 10 | 91.9 | 6.0 | 1.2 | 1.0 | — | — | — | — | — | 5.0 | — | — | 11.4 | 3.5 |
| 11 | 91.9 | 6.0 | 1.2 | 1.0 | — | — | — | — | — | — | 5.0 | — | 11.5 | 2.4 |
| 12 | 91.9 | 6.0 | 1.2 | 1.0 | — | — | — | — | — | — | — | 5.0 | 11.3 | 4.6 |

A = Deionized water;
B = 35% TEAH;
C = 51.9% periodic acid;
D = 85% lactic acid;
E = 0.2% Benzalkonium chloride;
F = 0.2% BTEAC;
G = 0.2% hexamethonium chloride;
H = 0.2% Dimethyldioctadecylammonium chloride;
I = Decyltrimethylammonium chloride;
J = 0.2% Dodecyltrimethyl ammonium chloride;
K = 0.2% Trimethyltetradecyl ammonium chloride;
L = 0.2% Cetyltrimethylammonium chloride

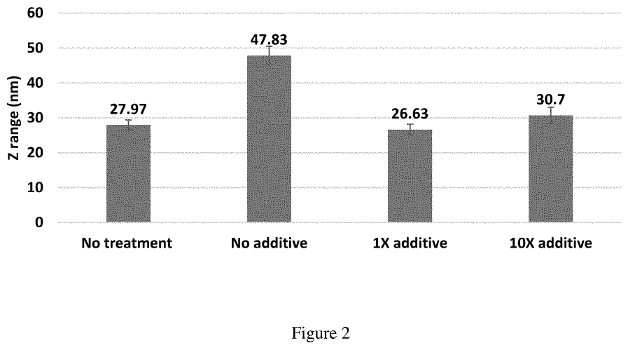

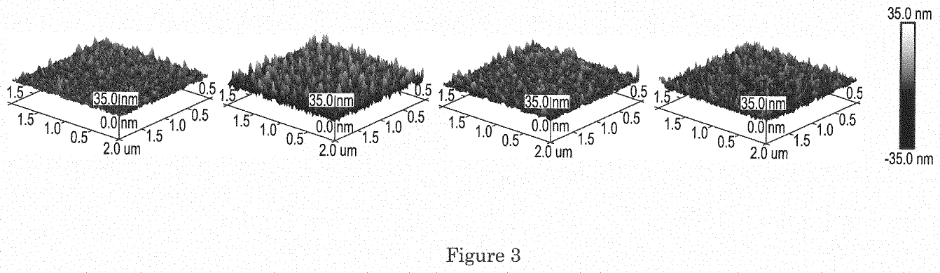

As the data in Table 2 shown, the surface roughness of the etched surfaces using compositions of the present disclosure were lower than the surface roughness that resulted from the control composition. The surface roughness prior to etching was 3.4. In addition, FIG. 2 is a bar graph showing the Z range for these compositions, illustrating the improved roughness parameters for molybdenum-containing films subjected to etching using the compositions of the present disclosure. (Rz is the mean value of a of roughness depths of consecutive sampling lengths. Z is the sum of the height of the highest peaks and the lowest valley depth within a sampling length.). Furthermore, FIG. 3 shows a scanning electron micrograph (SEM) of some of these surfaces, showing the roughness (Rz) is much higher in samples which were etched with compositions not containing a cationic surfactant.

Additional compositions of the present disclosure are also shown in Table 3, which also resulted in improved surface roughness.

TABLE 3

| Formulation | | | | | | | | | | | | | | |
|---|---|---|---|---|---|---|---|---|---|---|---|---|---|---|
| No. ↓ | A | B | C | D | E | N | O | P | Q | R | S | — | pH | Rz |
| 13 | 81.2 | 6.4 | 1.9 | — | 10 | — | — | — | 0.5 | — | — | — | 11.0 | 3.9 |
| 14 | 82.6 | — | 1.9 | — | — | 5.0 | 10 | — | 0.5 | — | — | — | 9.8 | 3.5 |
| 15 | 82.8 | 4.8 | 1.9 | — | — | — | 10 | — | 0.5 | — | — | — | 9.9 | 3.3 |
| 16 | 81.1 | 6.5 | 1.9 | — | — | — | 10 | — | 0.5 | — | — | — | 11.1 | 3.9 |
| 17 | 81.0 | 6.6 | 1.9 | — | — | — | — | 10 | 0.5 | — | — | — | 11.1 | 3.8 |
| 18 | 81.7 | 5.9 | 1.9 | — | — | — | 10 | — | — | 0.5 | — | — | 10.0 | 3.2 |
| 19 | 85.1 | 3.5 | 1.2 | — | — | — | 10 | — | 0.1 | — | 0.1 | — | 11.4 | 3.8 |

A = Deionized water;
B = 35% TEAH;
C = 51.9% periodic acid;
E = 0.2% Benzalkonium chloride;
N = 20% TMAH;
O = Benzyldodecyldimethylammonium chloride;
P = Benzyltetradecylammonium chloride;
Q = 1,2,4 triazole;
R = Ammonium phosphate dibasic;
S = Ammonium bicarbonate

Aspects

In a first aspect, the disclosure provides a selective etching composition comprising:
at least one oxidizing agent,
at least one cationic surfactant,
water, and
an amount of a pH adjustor necessary to achieve a pH of about 7 to about 13, and optionally comprising one or more of:
at least one complexing agent,
at least one pH buffering agent, or
at least one oxidizing agent stabilizer,
   wherein the selective etching composition removes molybdenum-containing films from a microelectronic device relative to aluminum oxide.

In a second aspect, the disclosure provides the composition of the first aspect, wherein the oxidizing agent is chosen from hydrogen peroxide, FeCl₃, FeF₃, Fe(NO₃)₃, Sr(NO₃)₂, CoF₃, MnF₃, oxone, (2KHSO₅·KHSO₄·K₂SO₄), nitric acid, ammonium peroxomonosulfate, ammonium chlorite (NH₄ClO₂), ammonium chlorate (NH₄ClO₃), ammonium iodate (NH₄IO₃), ammonium nitrate (NH₄NO₃), ammonium perborate (NH₄BO₃), ammonium perchlorate (NH₄ClO₄), ammonium periodate (NH₄IO₄), ammonium persulfate ((NH₄)₂S₂O₈), ammonium hypochlorite (NH₄ClO), ammonium tungstate ((NH₄)₁H₂(W₂O₇)), sodium persulfate (Na₂S₂O₈), sodium hypochlorite (NaClO), sodium perborate, potassium iodate (KlO₃), potassium permanganate (KMnO₄), potassium persulfate (K₂S₂O₈), potassium hypochlorite (KClO), tetramethylammonium chlorite ((N(CH₃)₄)ClO₂), tetramethylammonium chlorate ((N(CH₃)₄)ClO₃), tetramethylammonium iodate ((N(CH₃)₄)IO₃), tetramethylammonium perborate ((N(CH₃)₄)BO₃), tetramethylammonium perchlorate ((N(CH₃)₄)ClO₄), tetramethylammonium periodate ((N(CH₃)₄)IO₄), tetramethylammonium persulfate ((N(CH₃)₄)S₂O₈), tetrabutylammonium peroxomonosulfate, peroxomono sulfuric acid, urea hydrogen peroxide ((CO(NH₂)₂)H₂O₂), peracetic acid, t-butyl hydroperoxide, nitrobenzensulfonate, 1,4-benzoquinone, toluquinone, dimethyl-1,4-benzoquinone, chloranil, alloxan, periodic acid, and combinations thereof.

In a third aspect, the disclosure provides the composition of the first or second aspects, wherein the oxidizing agent is chosen from hydrogen peroxide, periodic acid, t-butyl hydroperoxide, potassium iodate, and peracetic acid.

In a fourth aspect, the disclosure provides the composition of the first through third aspects, wherein the cationic surfactant is chosen from cetyl trimethylammonium bromide, hexadecyltrimethyl ammonium chloride, heptadecanefluorooctane sulfonic acid, tetraethylammonium halides, stearyl trimethylammonium chloride, 4-(4-diethylaminophenylazo)-1-(4-nitrobenzyl)pyridium bromide, cetylpyridinium chloride monohydrate, benzalkonium chloride, benzethonium chloride benzyldimethyldodecylammonium chloride, benzyldimethylhexadecylammonium chloride, hexadecyltrimethylammonium bromide, dimethyldioctadecylammonium chloride, dodecyltrimethylammonium chloride, didodecyldimethylammonium bromide, di(hydrogenated tallow)dimethylammonium chloride, tetraheptylammonium bromide, tetrakis(decyl)ammonium bromide, and oxyphenonium bromide, dimethyldioctadecylammonium chloride, dimethyldihexadecylammonium bromide, di(hydrogenated tallow)dimethylammonium chloride, benzyldimethylammonium chloride, and benzyldimethylammonium bromide.

In a fifth aspect, the disclosure provides the composition of the first through fourth aspects, wherein the cationic surfactant is chosen from benzyldimethylammonium chloride, cetyl trimethylammonium bromide, hexamethonium chloride, trimethyltetradecylammonium chloride, decyltrimethylammonium chloride, and benzyldimethyldodecylammonium chloride.

In a sixth aspect, the disclosure provides the composition of the first through fifth aspects, wherein the pH adjustor is chosen from alkali metal hydroxides, alkaline earth metal hydroxides, tetramethylammonium hydroxide (TMAH), tetraethylammonium hydroxide (TEAH), tetrapropylammonium hydroxide (TPAH), tetrabutylammonium hydroxide (TB AH), tributylmethylammonium hydroxide (TB MAH), benzyltrimethylammonium hydroxide (BTMAH), choline hydroxide, ethyltrimethylammonium hydroxide, tris(2-hydroxyethyl)methyl ammonium hydroxide, diethyldimethylammonium hydroxide, tetrabutylphosphonium hydroxide (TBPH), tetramethylphosphonium hydroxide, tetraethylphosphonium hydroxide, tetrapropylphosphonium hydroxide, benzyltriphenylphosphonium hydroxide, methyl triphenylphosphonium hydroxide, ethyl triphenylphosphonium hydroxide, N-propyl triphenylphosphonium hydroxide, and combinations thereof.

In a seventh aspect, the disclosure provides the composition of first through sixth aspects, wherein the pH adjustor is chosen from tetramethylammonium hydroxide, choline hydroxide, or a combination thereof.

In an eighth aspect, the disclosure provides the composition of first through seventh aspects, wherein the composition comprises at least one complexing agent.

In a ninth aspect, the disclosure provides the composition of the first through eighth aspects, wherein the complexing agent is chosen from aminoethylethanolamine, N-methylaminoethanol, aminoethoxyethanol, dimethylaminoethoxyethanol, diethanolamine, N-methyldiethanolamine, monoethanolamine, triethanolamine, 1-amino-2-propanol, 2-amino butanol, isobutanolamine, triethylenediamine, 4-(2-hydroxyethyl)morpholine, ethylenediamine tetraacetic acid, m-xylenediamine, iminodiacetic acid, 2-(hydroxyethyl)iminodiacetic acid, nitrilotriacetic acid, thiourea, 1,1,3,3-tetramethylurea, urea, urea derivatives, uric acid, alanine, arginine, asparagine, aspartic acid, cysteine, glutamic acid, glutamine, histidine, isoleucine, leucine, lysine, methionine, phenylalanine, proline, serine, threonine, tryptophan, tyrosine, valine, 1-hydroxyethylidene-1,1-diphosphonic acid, 1,5,9-triazacyclododecane-N,N′,N″-tris(methylenephosphonic acid), 1,4,7,10-tetraazacyclododecane-N,N′,N″,N′″-tetrakis(methylenephosphonic acid), nitrilotris(methylene)triphosphonic acid, diethylenetriaminepentakis(methylene phosphonic acid), aminotri(methylene phosphonic acid), bis(hexamethylene)triamine pentamethylene phosphonic acid, 1,4,7-triazacyclononane-N,N′,N″-tris(methylenephosphonic acid, hydroxyethyldiphosphonate, nitrilotris(methylene)phosphonic acid, 2-phosphono-butane-1,2,3,4-tetracarboxylic, carboxyethyl phosphonic acid, aminoethyl phosphonic acid, glyphosate, ethylene diamine tetra(methylenephosphonic acid) phenylphosphonic acid, oxalic acid, succinnic acid, maleic acid, malic acid, malonic acid, adipic acid, phthalic acid, lactic acid, citric acid, sodium citrate, potassium citrate, ammonium citrate, tricarballylic acid, trimethylolpropionic acid, tartaric acid, glucuronic acid, 2-carboxypyridine, 4,5-dihydroxy-1,3-benzenedisulfonic acid disodium salt, and combinations thereof.

In a tenth aspect, the disclosure provides the composition of the first through ninth aspects, wherein the complexing agent is chosen from 1-hydroxyethylidene-1,1-diphosphonic acid, lactic acid, and citric acid.

In an eleventh aspect, the disclosure provides the composition of the first through tenth aspects, wherein the at least one pH buffering agent is a metal corrosion inhibitor or an ammonium salt.

In a twelfth aspect, the disclosure provides the composition of the eleventh aspect, wherein the metal corrosion inhibitor is chosen from 5-aminotetrazole, 5-phenyl-benzotriazole, 1H-tetrazole-5-acetic acid, 1-phenyl-2-tetrazoline-5-thione, benzimidazole, methyltetrazole, pyrazoles, 5-amino-1,3,4-thiadiazole-2-thiol, benzotriazole, 1,2,4-triazole, 1,2,3-triazole, tolyltriazole, 5-methyl-benzotriazole, 5-phenyl-benzotriazole, 5-nitro-benzotriazole, benzotriazole carboxylic acid, 3-amino-5-mercapto-1,2,4-triazole, 1-amino-1,2,4-triazole, hydroxybenzotriazole, 2-(5-amino-pentyl)-benzotriazole, 1-amino-1,2,3-triazole, 1-amino methyl-1,2,3-triazole, 3-amino-1,2,4-triazole, 3-mercapto-1,2,4-triazole, 3-isopropyl-1,2,4-triazole, 5-phenylthiol-benzotriazole, halo-benzotriazoles, naphthotriazole, 2-mercaptobenzimidazole, 2-mercaptobenzothiazole, 4-methyl-2-phenylimidazole, 2-mercaptothiazoline, 5-amino-1,2,4-triazole, 3-amino-5-mercapto-1,2,4-triazole, pentylenetetrazole, 5-phenyl-1H-tetrazole, 5-benzyl-1H-tetrazole, 2,4-diamino-6-methyl-1,3,5-triazine, thiazole, triazine, methyltetrazole, 1,3-dimethyl-2-imidazolidinone, 1,5-pentamethylenetetrazole, 1-phenyl-5-mercaptotetrazole, diaminomethyltriazine, imidazoline thione, 4-methyl-4H-1,2,4-triazole-3-thiol, 4-amino-4H-1,2,4-triazole, 3-amino-5-methylthio-1H-1,2,4-triazole, benzothiazole, imidazole, indiazole, adenine, adenosine, carbazole, N-cyclohexyl-3-aminopropanesulfonic acid, and combinations thereof.

In a thirteenth aspect, the disclosure provides the composition of eleventh or twelfth aspects, wherein the metal corrosion inhibitor is tolyltriazole.

In a fourteenth aspect, the disclosure provides the composition of claim eleventh aspect, wherein the ammonium salt is chosen from salts of ammonium acetate, ammonium bicarbonate, ammonium butyrate, ammonium trifluoroacetate, diammonium monohydrogen phosphate, ammonium dihydrogen phosphate, ammonium phosphonate, and combinations thereof.

In a fifteenth aspect, the disclosure provides the composition of the first through fourteenth aspects, further comprising an oxidizing agent stabilizer.

In a sixteenth aspect, the disclosure provides the composition of the fifteenth aspect, wherein the oxidizing agent stabilizer is chosen from glycine, serine, proline, leucine, alanine, asparagine, aspartic acid, glutamine, valine, and lysine, nitrilotriacetic acid, iminodiacetic acid, etidronic acid, ethylenediaminetetraacetic acid (EDTA), (1,2-cyclohexylenedinitrilo)tetraacetic acid (CDTA), uric acid, tetraglyme, diethylenetriamine pentaacetic acid, propylenediamine tetraacetic acid, ethylendiamine disuccinic acid, sulfanilamide, and combinations thereof.

In a seventeenth aspect, the disclosure provides the composition of the fifteenth or sixteenth aspects, wherein the oxidizing agent stabilizer is chosen from ethylenediaminetetraacetic acid, (1,2-cyclohexylenedinitrilo)tetraacetic acid, and tetraglyme.

In an eighteenth aspect, the disclosure provides the composition of the first through seventeenth aspects, further comprising at least one organic solvent.

In a nineteenth aspect, the disclosure provides the composition of the eighteenth aspect, wherein the organic solvent is propylene glycol.

In a twentieth aspect, the disclosure provides a method of etching molybdenum from a microelectronic device substrate having a molybdenum-containing film and aluminum oxide thereon, the method comprising contacting the microelectronic device substrate with a composition comprising:
at least one oxidizing agent,
at least one cationic surfactant,
water, and
an amount of a pH adjustor necessary to achieve a pH of about 7 to about 13, and optionally comprising one or more of:
at least one complexing agent,
at least one pH buffering agent, or
at least one oxidizing agent stabilizer,
   for a period of time sufficient to at least partially remove the molybdenum-containing film relative to the aluminum oxide.

Having thus described several illustrative embodiments of the present disclosure, those of skill in the art will readily appreciate that yet other embodiments may be made and used within the scope of the claims hereto attached. Numerous advantages of the disclosure covered by this document have been set forth in the foregoing description. It will be understood, however, that this disclosure is, in many respects, only illustrative. The disclosure's scope is, of course, defined in the language in which the appended claims are expressed.

What is claimed is:

1. A selective etching composition comprising:
at least one oxidizing agent,
at least one cationic surfactant,
water, and
an amount of a pH adjustor necessary to achieve a pH of about 7 to about 13, and optionally comprising one or more of:
at least one complexing agent,
at least one pH buffering agent, or
at least one oxidizing agent stabilizer,
wherein the selective etching composition removes molybdenum-containing films from a microelectronic device relative to aluminum oxide.

2. The composition of claim 1, wherein the oxidizing agent is chosen from hydrogen peroxide, FeCl₃, FeF₃, Fe(NO₃)₃, Sr(NO₃)₂, CoF₃, MnF₃, oxone, (2KHSO₅·KHSO₄·K₂SO₄), nitric acid, ammonium peroxomonosulfate, ammonium chlorite (NH₄ClO₂), ammonium chlorate (NH₄ClO₃), ammonium iodate (NH₄IO₃), ammonium nitrate (NH₄NO₃), ammonium perborate (NH₄BO₃), ammonium perchlorate (NH₄ClO₄), ammonium periodate (NH₄IO₄), ammonium persulfate ((NH₄)₂S₂O₈), ammonium hypochlorite (NH₄ClO), ammonium tungstate ((NH₄)₁₀H₂ (W₂O₇)), sodium persulfate (Na₂S₂O₈), sodium hypochlorite (NaClO), sodium perborate, potassium iodate (KIO₃), potassium permanganate (KMnO₄), potassium persulfate (K₂S₂O₈), potassium hypochlorite (KClO), tetramethylammonium chlorite ((N(CH₃)₄)ClO₂), tetramethylammonium chlorate ((N(CH₃)₄)ClO₃), tetramethylammonium iodate ((N(CH₃)₄)IO₃), tetramethylammonium perborate ((N(CH₃)₄)BO₃), tetramethylammonium perchlorate ((N(CH₃)₄)ClO₄), tetramethylammonium periodate ((N(CH₃)₄)IO₄), tetramethylammonium persulfate ((N(CH₃)₄)S₂O₈), tetrabutylammonium peroxomonosulfate, peroxomonosulfuric acid, urea hydrogen peroxide ((CO(NH₂)₂)H₂O₂), peracetic acid, t-butyl hydroperoxide, nitrobenzensulfonate, 1,4-benzoquinone, toluquinone, dimethyl-1,4-benzoquinone, chloranil, alloxan, periodic acid, and combinations thereof.

3. The composition of claim 1, wherein the oxidizing agent is chosen from hydrogen peroxide, periodic acid, t-butyl hydroperoxide, potassium iodate, and peracetic acid.

4. The composition of claim 1, wherein the cationic surfactant is chosen from cetyl trimethylammonium bromide, hexadecyltrimethyl ammonium chloride, heptadecanefluorooctane sulfonic acid, tetraethylammonium halides, stearyl trimethylammonium chloride, 4-(4-diethylaminophenylazo)-1-(4-nitrobenzyl)pyridium bromide, cetylpyridinium chloride monohydrate, benzalkonium chloride, benzethonium chloride benzyldimethyldodecylammonium chloride, benzyldimethylhexadecylammonium chloride, hexadecyltrimethylammonium bromide, dimethyldioctadecylammonium chloride, dodecyltrimethylammonium chloride, didodecyldimethylammonium bromide, di(hydrogenated tallow)dimethylammonium chloride, tetraheptylammonium bromide, tetrakis(decyl)ammonium bromide, and oxyphenonium bromide, dimethyldioctadecylammonium chloride, dimethyldihexadecylammonium bromide, di(hydrogenated tallow)dimethylammonium chloride, benzyldimethylammonium chloride, and benzyldimethylammonium bromide.

5. The composition of claim 4, wherein the cationic surfactant is chosen from benzyldimethylammonium chloride, cetyl trimethylammonium bromide, hexamethonium chloride, trimethyltetradecylammonium chloride, decyltrimethylammonium chloride, and benzyldimethyldodecylammonium chloride.

6. The composition of claim 1, wherein the pH adjustor is chosen from alkali metal hydroxides, alkaline earth metal hydroxides, tetramethylammonium hydroxide (TMAH), tetraethylammonium hydroxide (TEAH), tetrapropylammonium hydroxide (TPAH), tetrabutylammonium hydroxide (TBAH), tributylmethylammonium hydroxide (TBMAH), benzyltrimethylammonium hydroxide (BTMAH), choline hydroxide, ethyltrimethylammonium hydroxide, tris(2-hydroxyethyl)methyl ammonium hydroxide, diethyldimethylammonium hydroxide, tetrabutylphosphonium hydroxide (TBPH), tetramethylphosphonium hydroxide, tetraethylphosphonium hydroxide, tetrapropylphosphonium hydroxide, benzyltriphenylphosphonium hydroxide, methyl triphenylphosphonium hydroxide, ethyl triphenylphosphonium hydroxide, N-propyl triphenylphosphonium hydroxide, and combinations thereof.

7. The composition of claim 6, wherein the pH adjustor is chosen from tetramethylammonium hydroxide, choline hydroxide, or a combination thereof.

8. The composition of claim 1, wherein the composition comprises at least one complexing agent.

9. The composition of claim 8, wherein the complexing agent is chosen from aminoethylethanolamine, N-methylaminoethanol, aminoethoxyethanol, dimethylaminoethoxyethanol, diethanolamine, N-methyldiethanolamine, monoethanolamine, triethanolamine, 1-amino-2-propanol, 2-amino-1-butanol, isobutanolamine, triethylenediamine, 4-(2-hydroxyethyl)morpholine, ethylenediamine tetraacetic acid, m-xylenediamine, iminodiacetic acid, 2-(hydroxyethyl)iminodiacetic acid, nitrilotriacetic acid, thiourea, 1,1,3,3-tetramethylurea, urea, urea derivatives, uric acid, alanine, arginine, asparagine, aspartic acid, cysteine, glutamic acid, glutamine, histidine, isoleucine, leucine, lysine, methionine, phenylalanine, proline, serine, threonine, tryptophan, tyrosine, valine, 1-hydroxyethylidene-1,1-diphosphonic acid, 1,5,9-triazacyclododecane-N,N′,N″-tris(methylenephosphonic acid), 1,4,7,10-tetraazacyclododecane-N,N′,N″,N′″-tetrakis(methylenephosphonic acid), nitrilotris(methylene)triphosphonic acid, diethylenetriaminepentakis(methylene phosphonic acid), aminotri(methylene phosphonic acid), bis(hexamethylene)triamine pentamethylene phosphonic acid, 1,4,7-triazacyclononane-N,N′,N″-tris(methylenephosphonic acid, hydroxyethyldiphosphonate, nitrilotris(methylene)phosphonic acid, 2-phosphono-butane-1,2,3,4-tetracarboxylic, carboxyethyl phosphonic acid, aminoethyl phosphonic acid, glyphosate, ethylene diamine tetra(methylenephosphonic acid) phenylphosphonic acid, oxalic acid, succinnic acid, maleic acid, malic acid, malonic acid, adipic acid, phthalic acid, lactic acid, citric acid, sodium citrate, potassium citrate, ammonium citrate, tricarballylic acid, trimethylolpropionic acid, tartaric acid, glucuronic acid, 2-carboxypyridine, 4,5-dihydroxy-1,3-benzenedisulfonic acid disodium salt, and combinations thereof.

10. The composition of claim 9, wherein the complexing agent is chosen from 1-hydroxyethylidene-1,1-diphosphonic acid, lactic acid, and citric acid.

11. The composition of claim 1, wherein the composition comprising at least one pH buffering agent is a metal corrosion inhibitor or an ammonium salt.

12. The composition of claim 11, wherein the metal corrosion inhibitor is chosen from 5-aminotetrazole, 5-phenyl-benzotriazole, 1H-tetrazole-5-acetic acid, 1-phenyl-2-tetrazoline-5-thione, benzimidazole, methyltetrazole, pyrazoles, 5-amino-1,3,4-thiadiazole-2-thiol, benzotriazole, 1,2,4-triazole, 1,2,3-triazole, tolyltriazole, 5-methyl-benzotriazole, 5-phenyl-benzotriazole, 5-nitro-benzotriazole, benzotriazole carboxylic acid, 3-amino-5-mercapto-1,2,4-triazole, 1-amino-1,2,4-triazole, hydroxybenzotriazole, 2-(5-amino-pentyl)-benzotriazole, 1-amino-1,2,3-triazole, 1-amino-5-methyl-1,2,3-triazole, 3-amino-1,2,4-triazole, 3-mercapto-1,2,4-triazole, 3-isopropyl-1,2,4-triazole, 5-phenylthiol-benzotriazole, halo-benzotriazoles, naphthotriazole, 2-mercaptobenzimidazole, 2-mercaptobenzothiazole, 4-methyl-2-phenylimidazole, 2-mercaptothiazoline, 5-amino-1,2,4-triazole, 3-amino-5-mercapto-1,2,4-triazole, pentylenetetrazole, 5-phenyl-1H-tetrazole, 5-benzyl-1H-tetrazole, 2,4-diamino-6-methyl-1,3,5-triazine, thiazole, triazine, methyltetrazole, 1,3-dimethyl-2-imidazolidinone, 1,5-pentamethylenetetrazole, 1-phenyl-5-mercaptotetrazole, diaminomethyltriazine, imidazoline thione, 4-methyl-4H-1,2,4-triazole-3-thiol, 4-amino-4H-1,2,4-triazole, 3-amino-5-methylthio-1H-1,2,4-triazole, benzothiazole, imidazole, indiazole, adenine, adenosine, carbazole, N-cyclohexyl-3-aminopropanesulfonic acid, and combinations thereof.

13. The composition of claim 12, wherein the metal corrosion inhibitor is tolyltriazole.

14. The composition of claim 11, wherein the ammonium salt is chosen from salts of ammonium acetate, ammonium bicarbonate, ammonium butyrate, ammonium trifluoroacetate, diammonium monohydrogen phosphate, ammonium dihydrogen phosphate, ammonium phosphonate, and combinations thereof.

15. The composition of claim 1, further comprising an oxidizing agent stabilizer.

16. The composition of claim 15, wherein the oxidizing agent stabilizer is chosen from glycine, serine, proline, leucine, alanine, asparagine, aspartic acid, glutamine, valine, and lysine, nitrilotriacetic acid, iminodiacetic acid, etidronic acid, ethylenediaminetetraacetic acid (EDTA), (1,2-cyclohexylenedinitrilo)tetraacetic acid (CDTA), uric acid, tetraglyme, diethylenetriamine pentaacetic acid, propylenediamine tetraacetic acid, ethylendiamine disuccinic acid, sulfanilamide, and combinations thereof.

17. The composition of claim 15, wherein the oxidizing agent stabilizer is chosen from ethylenediaminetetraacetic acid, (1,2-cyclohexylenedinitrilo)tetraacetic acid, and tetraglyme.

18. The composition of claim 1, further comprising at least one organic solvent.

19. The composition of claim 18, wherein the organic solvent is propylene glycol.

20. A method of etching molybdenum from a microelectronic device substrate having a molybdenum-containing film and aluminum oxide thereon, the method comprising contacting the microelectronic device substrate with a composition comprising:
at least one oxidizing agent,
at least one cationic surfactant,
water, and
an amount of a pH adjustor necessary to achieve a pH of about 7 to about 13, and optionally comprising one or more of:
at least one complexing agent,
at least one pH buffering agent, or
at least one oxidizing agent stabilizer,
for a period of time sufficient to at least partially remove the molybdenum-containing film relative to the aluminum oxide.
